(19) United States
(12) Patent Application Publication
(10) Pub. No.: US 2004/0164676 A1
(43) Pub. Date: Aug. 26, 2004

(54) Display apparatus and a desiccant for the same

(76) Inventors: Tetsuji Omura, Ogaki-shi (JP); Toru Sasatani, Motosu-gun (JP)

Correspondence Address: CANTOR COLBURN, LLP, 55 GRIFFIN ROAD SOUTH, BLOOMFIELD, CT, 06002

(21) Appl. No.: 10/728,147

(22) Filed: Dec. 4, 2003

(30) Foreign Application Priority Data
Dec. 4, 2002 (JP) 2002-352980

(51) Int. Cl. H05B 33/04

(52) U.S. Cl. 313/512; 313/506

(57) ABSTRACT

An upper area over an element substrate is sealed by a sealing substrate to which a desiccant is fixed on an internal surface of the sealing substrate. A substance prepared by dispersing moisture absorbent grains into an adhesive made of resin is used as the desiccant. Further, the size of the moisture absorbent grains is defined to be equal to or smaller than 10 μm. In this manner, the desiccant can be prevented from cracking due to temperature variations.

### BACKGROUND OF THE INVENTION

1. Field of the Invention

The present invention relates to a display apparatus in which display operation is executed by controlling emission of each pixels disposed in a matrix, and more particularly to a desiccant which is suitable for the display apparatus.

2. Description of the Related Art

Organic electroluminescence display panels (organic EL panels) are one known type of flat display panel. Because, unlike a liquid crystal display (LCD) panel, an organic display panel is self-emitting, there is growing expectation that organic electroluminescence displays will become widely used as well-lit, high-viewability flat display panels.

An organic EL panel is typically configured by arranging a plurality of organic EL elements as pixels in a matrix. A passive type and an active type driving method, similarly to LCDs, are available as a method for driving the organic EL elements, and an active matrix type driving method is considered to be more preferable, as in the case of LCDs. More specifically, because display with high resolution can be realized by the active matrix driving method in which switching elements (usually, two switching elements: one for switching and one for driving) are provided for every pixel and display on each pixel is controlled by controlling the switching elements, the active matrix driving method is more preferable to a passive driving method in which there is no switching element provided on a pixel-by-pixel basis.

Here, the organic EL elements are emitted by the passage of a current through an organic emitting layer. However, these organic layers are prone to degradation due to moisture.

Accordingly, with respect to an element substrate on which the organic EL elements are provided in an organic EL display panel, upper space located over a display region where the organic EL elements are to be disposed (where pixels are existing) is covered with a cap (a sealing substrate) which is adhered to the element substrate at the perimeter of the cap for establishing the upper space as hermetic space, and a desiccant is placed in the space, to thereby preclude moisture. In other words, by fixing the desiccant on an inner surface of the sealing substrate, moisture contained in the upper space over the organic EL elements is eliminated through the desiccant.

It should be noted that such a desiccant is described in Japanese Patent Laid-Open Publication No. Hei 11-312581 etc.

Conventional organic EL display panels such as described above, however, suffer from a problem that the desiccant could come unstuck and the unstuck desiccant damages the element substrate.

### SUMMARY OF THE INVENTION

According to the present invention, the size of moisture absorbent grains to be dispersed into an adhesive is defined to be equal to or smaller than 10 μm. This definition can minimize the risk of producing cracking of a desiccant due to temperature variations, which results in the solution of the problem caused by, for example, the unstuck desiccant.

### BRIEF DESCRIPTION OF THE DRAWINGS

FIG. 1 shows a structure of a display apparatus according to an embodiment;

FIG. 2 shows an adhered state of a desiccant;

FIG. 3 shows cracks on the desiccant, and

FIG. 4 is a diagram showing a relationship between grain size of a moisture absorbent and occurrence of a crack on the desiccant.

### DESCRIPTION OF THE PREFERRED EMBODIMENTS

Referring to drawings, an embodiment of the present invention will be described below.

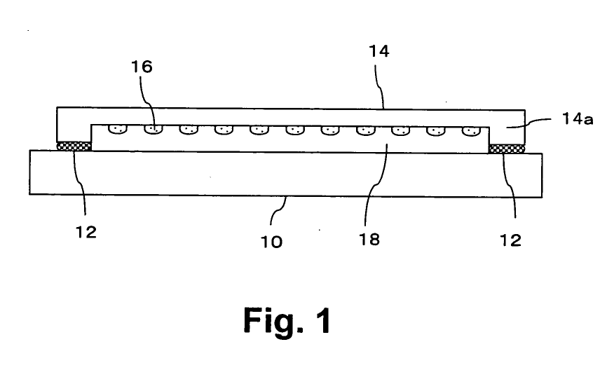

FIG. 1 is a schematic diagram showing a structural overview of a display apparatus according to the present embodiment. An element substrate 10 is made of a glass substrate, and on the element substrate 10, a great number of TFTs, wiring, and organic EL elements disposed in a matrix are formed. In particular, the organic EL elements and a pixel circuit for driving the organic EL elements are provided for every pixel.

A peripheral driver circuit placed at the periphery of a pixel region on which pixels are formed generates a predetermined signal according to display data supplied from the outside, which causes the organic EL elements for each pixel to emit according to the display data, to thereby carry out desired display.

On the periphery of the element substrate 10, a sealing substrate 14 is adhered by a sealant 12. The sealing substrate 14 is made of, for example, glass and hollowed out leaving a surrounding area so as to take on the shape of a cap. Accordingly, the sealing substrate 14 has, in the surrounding area, a protrusion 14a which is adhered to the periphery of the element substrate 10 using the sealant 12.

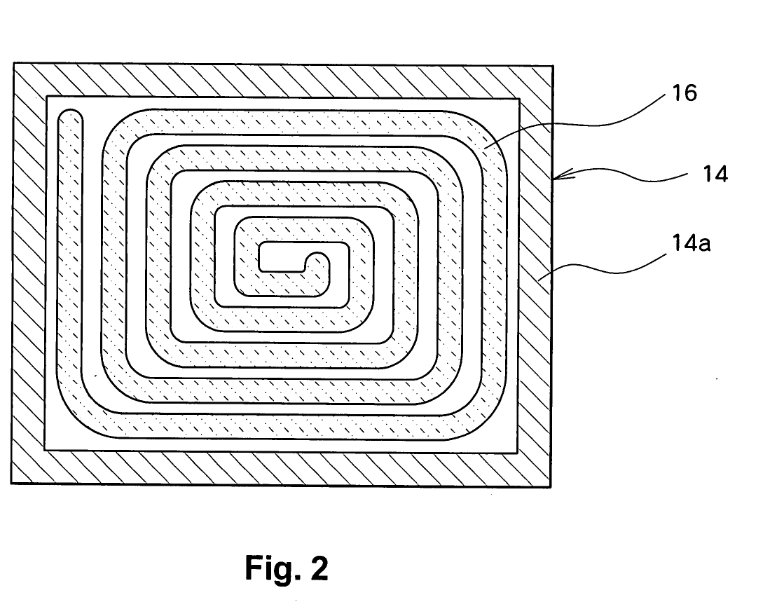

Further, a desiccant 16 is formed adhering to an internal surface of the sealing substrate 14 which is opposed to the element substrate 10. The desiccant 16 is shaped, for example, in a spiral as shown in FIG. 2 having a thickness of approximately 10 to 150 μm and a width of approximately 1000 to 2000 μm.

Here, the sealing substrate 14 should be prepared in a state where the desiccant 16 is formed before the element substrate 10 is completed. This preparation is made in a dry environment. Then, the sealant 12 is adhered to either the sealing substrate 14 or the element substrate 10 also in the dry environment, for example, in a depressed atmosphere of nitrogen, and then the sealing substrate 14 is pressed against the element substrate 10 for joining.

In this manner, internal space 18 formed by the element substrate 10 and the sealing substrate 14 is sealed and dried. Further, the desiccant 16 takes up moisture introduced from the elements or other components on the element substrate 10 and moisture that enters into the internal space from the outside via the sealant 12. As a result, decrease of lifespan of an organic layer etc. on the element substrate 10 can be prevented effectively.

Here, it should be noted that the desiccant 16 in this embodiment is a thermoplastic resin (an adhesive) of, for example, acrylic into which moisture absorbent (for example, CaO) grains are dispersedly introduced. Although the desiccant 16 contains a solvent therein, thereby being in a slightly fluidized state when it is formed and adhered to the sealing substrate 14, the solvent is vaporized afterward so that the desiccant 16 is hardened.

The size of the moisture absorbent grains in this embodiment is specified to 10 μm or smaller. With this specification, the thermoplastic resin is prevented from cracking due to, for example, temperature variations during use of the display apparatus, and thereby prevented from coming unstuck or falling off from the sealing substrate 14, which enables effective avoidance of detrimental effects on the components of the sealing substrate 14.

In order to verify that the display apparatus is resistant to the temperature variations during use, the display apparatus is subjected to a test, for example, to determine reliability by placing the display apparatus in an environment at temperatures of from −30° C. to 80° C. It should be noted that there is a significant difference in coefficients of thermal expansion between the moisture absorbent grains themselves and the desiccant containing the moisture absorbent grains.

Table 1 shows coefficients of thermal expansion for three moisture absorbents of CaO, BaO, and silica gel and an acrylic thermoplastic resin (an adhesive).

TABLE 1

| | Coefficient of thermal expansion |
|---|---|
| Moisture Absorbent | |
| CaO | 5 × 10⁻⁶ to 25 × 10⁻⁶ |
| BaO | 5 × 10⁻⁶ to 25 × 10⁻⁶ |
| Silica Gel | 1 × 10⁻⁶ to 15 × 10⁻⁶ |
| Adhesive | |
| Acrylic thermoplastic resin | 100 × 10⁻⁶ to 200 × 10⁻⁶ |

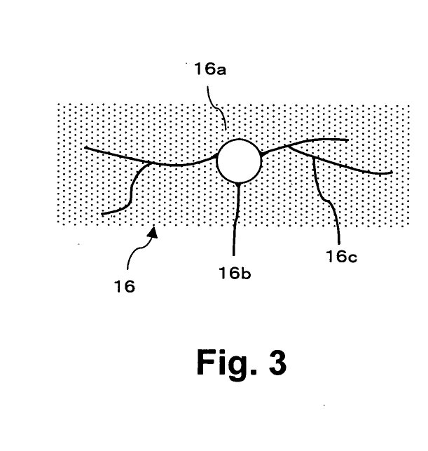

As can be seen from the table, the coefficient of thermal expansion of the adhesive is two orders of magnitude greater, compared with the coefficients of thermal expansion of the moisture absorbents. Such a significant difference in the coefficients of thermal expansion increases separation between the adhesive 16a and the moisture absorbent grains 16b at their interface based on the difference in the coefficients of thermal expansion when the temperature varies, which could often manifest itself in the form of, for example, cracks 16c as shown in FIG. 3.

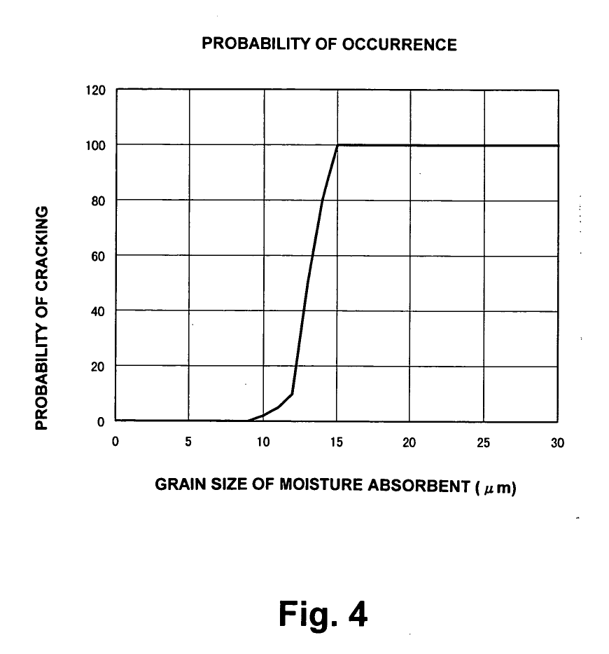

However, by conducting various experiments, a remarkable relationship between the size of the moisture absorbent grains and the probability of occurrence of cracking was found. More specifically, as shown in FIG. 4, the probability of occurrence of cracking increases sharply after the size of the moisture absorbent grains exceeds 10 μm, whereas almost no cracks appear when the size is equal to or smaller than 10 μm. Therefore, by using a desiccant prepared by dispersing moisture absorbent grains which are of the size equal to or smaller than 10 μm into an adhesive, the occurrence of cracking can be prevented in an efficient manner. It should be noted that although FIG. 3 shows an example in which CaO is used as the moisture absorbent and an acrylic thermoplastic resin is used as the adhesive, the above-listed three substances may be used for the moisture absorbent in general, or other moisture absorbents basically made of an inorganic substance and having a similar coefficient of thermal expansion may be employed. Regarding the coefficients of thermal expansion of thermoplastic resins which can be used as the adhesive, the difference between the thermoplastic resins is not so significant compared with the difference between the thermoplastic resin and the moisture absorbent. Therefore, it can be said that the grain size of the moisture absorbent may preferably be defined to be equal to or smaller than 10 μm.

Although there is no lower limit to the grain size of the moisture absorbent as long as the grain size does not exceed 10 μm, it is preferable that the grain size is greater than 0.1 μm because the moisture absorbent whose grain size is 0.1 μm or smaller has difficulties in, for example, dispersing into the adhesive. In other words, the grain size of from 0.1 to 10 μm is most amenable to the moisture absorbent grains.

When moisture absorbent grains having the coefficient of thermal expansion of approximately from 1×10⁻⁶ to 25×10⁻⁶ are dispersed into the adhesive having the coefficient of thermal expansion of approximately from 100×10⁻⁶ to 200×10⁻⁶, it can be said that the grain size of the moisture absorbent is preferably defined between approximately 0.1 to 10 μm.

In the above explanation, thermoplastic resin is used as the adhesive, however thermosetting resin or UV setting resin can also be used as the adhesive. The thermosetting resin and the UV setting resin also have the coefficient of thermal expansion of approximately from 100×10⁻⁶ to 200×10⁻⁶.

What is claimed is:

1. A display apparatus in which display operation is carried out by controlling emission of each pixel arranged in a matrix, the apparatus comprising:
an element substrate on which a luminous element is formed for each of the pixels;
a sealing substrate on which a protrusion is formed in a surrounding area thereof, the protrusion being adhered to the periphery of said element substrate so as to seal an upper space over said element substrate, and
a desiccant fixed on an internal surface of the sealing substrate opposed to the element substrate so as to make the upper space located over the element substrate dry, wherein
said desiccant consists of an adhesive made of resin and moisture absorbent grains dispersedly mixed into the adhesive, and
the size of said moisture absorbent grains is equal to or smaller than 10 μm.

2. A display apparatus according to claim 1, wherein said moisture absorbent grains are CaO grains.

3. A display apparatus according to claim 1, wherein said adhesive is a thermoplastic resin.

4. A display apparatus according to claim 3, wherein said thermoplastic resin is an acrylic resin or an epoxy resin.

5. A display apparatus according to claim 1, wherein the size of said moisture absorbent grains is between 0.1 μm and 10 μm.

6. A display apparatus according to claim 1, wherein said desiccant is formed in the shape of a spiral on a surface of the sealing substrate opposed to the element substrate.

7. A desiccant which absorbs moisture consisting of:
an adhesive of resin, and
moisture absorbent grains dispersedly mixed into the adhesive, wherein
the diameter of said moisture absorbent grains is equal to or smaller than 10 μm.

8. A desiccant according to claim 7, wherein said moisture absorbent grains are CaO grains or BaO grains.

9. A desiccant according to claim 7, wherein said adhesive is any one of a thermoplastic resin, thermosetting resin and UV setting resin.

10. A desiccant according to claim 9, wherein said thermoplastic resin is an acrylic resin or an epoxy resin.

11. A desiccant according to claim 7, wherein the size of said moisture absorbent grains is between 0.1 μm and 10 μm.
